(19) United States
(12) Patent Application Publication
(10) Pub. No.: US 2014/0047296 A1
(43) Pub. Date: Feb. 13, 2014

(54) Error Correcting Code Design For A Parity Enabled Memory

(71) Applicants: Iraj Motabar, Irvine, CA (US); Morteza Cyrus Afghahi, Irvine, CA (US)

(72) Inventors: Iraj Motabar, Irvine, CA (US); Morteza Cyrus Afghahi, Irvine, CA (US)

(73) Assignee: Broadcom Corporation, Irvine, CA (US)

(21) Appl. No.: 13/571,095

(22) Filed: Aug. 9, 2012

(51) Int. Cl. H03M 13/05; G06F 11/10

(52) U.S. Cl. 714/758; 714/E11.034

(57) ABSTRACT

A memory system provides Error Correcting Code (ECC) protection for data stored in a parity enabled memory. The memory may include designated parity locations for data stored in the memory. During write operations, the system may obtain data to write into the memory, compute ECC protection bits for the data, and store the ECC protection bits in locations in the memory designated as parity locations for the data. During read operations, the system may read data from the memory. The system may also read protection bits for the data from locations designated as parity locations for the data. Then, the system may interpret the protection bits as ECC protection bits instead of as parity bits. The system may provide ECC protection for data without additional overhead or memory configuration changes to the parity enabled memory.

### TECHNICAL FIELD

This disclosure relates to a memory device. This disclosure also relates to an Error Correcting Code (ECC) design for a parity enabled memory.

### BACKGROUND

With the rapid advance of technology in the past decades, complex electronic devices are in widespread use in virtually every context of day to day life. Vast communication networks support a continuous exchange of data between countless electronic devices, which may require certain levels of data reliability. Improvements in data reliability for electronic devices will help continue to drive the widespread adoption and demand for such electronic devices.

### BRIEF DESCRIPTION OF THE DRAWINGS

The innovation may be better understood with reference to the following drawings and description. In the figures, like reference numerals designate corresponding parts throughout the different views.

FIG. 1 shows a parity enabled memory system.

FIG. 2 shows an example of a system that provides ECC protection in a parity enabled memory.

FIG. 3 shows an example of an ECC word and ECC protection bits.

FIG. 4 shows an example of a system that provides ECC protection in a parity enabled memory.

FIG. 5 shows an example of a system for writing an ECC word into a parity enabled memory.

FIG. 6 shows an example of logic that may be implemented as hardware, software, or both.

FIG. 7 shows an example of a system for reading an ECC word from a parity enabled memory.

FIG. 8 shows an example of logic that may be implemented as hardware, software, or both.

### DETAILED DESCRIPTION

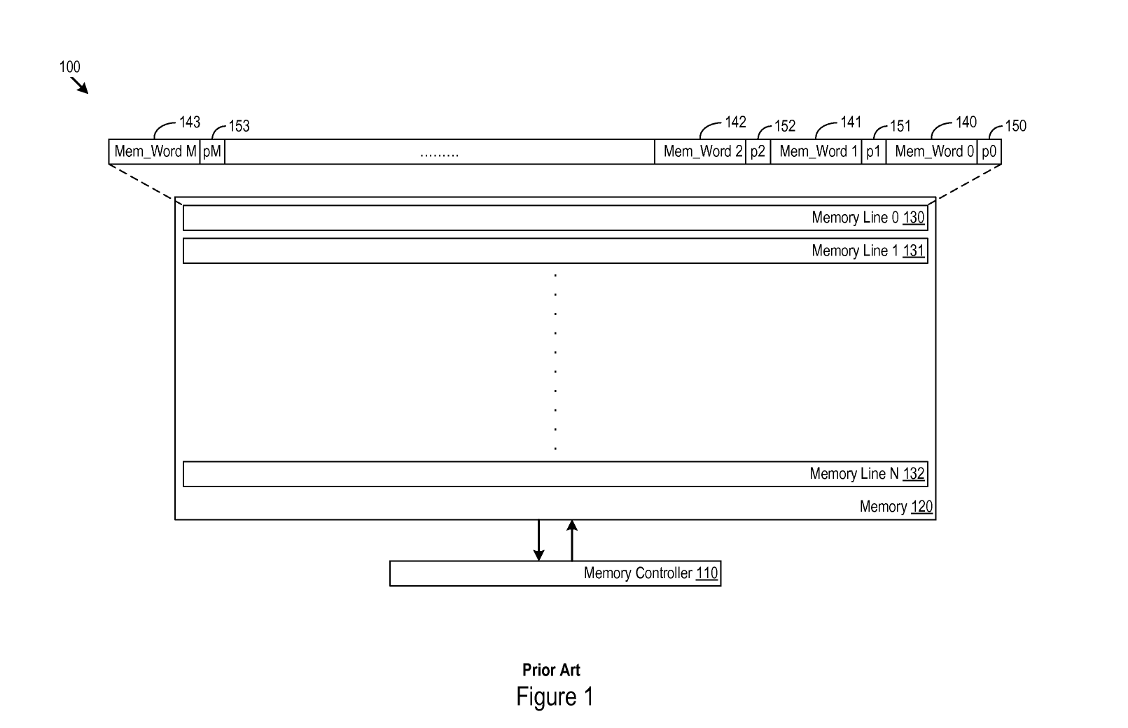

FIG. 1 shows a parity enabled memory system 100. The memory system 100 includes a memory controller 110 coupled to a memory 120. The memory 120 may be any type of memory, including as examples, a random access memory (RAM), a processor cache such as an L1 cache, L2 cache, or L3 cache, an external memory, non-volatile memory, or others. The memory controller 110 may communicate with the memory 120 to initiate write operations to and read operations from the memory 120. For example, the memory controller 110 may send various signals to the memory 120, including as examples a read enable signal, a write enable signal, a memory address, write data, parity of the write data, a memory clock signal, and more. The memory 120 may store memory data and parity protection data. Memory data may refer to data written to the memory, e.g., through the memory controller 110. Parity protection data may refer to parity data, e.g., bits, associated with a portion of the memory data.

The memory 120 stores data in any number of memory lines. In FIG. 1, the memory 120 includes N number of memory lines, including the memory lines labeled as Mem_Line 0 130, Mem_Line 1 131, and Mem_Line N 132. Each memory line may include any amount of memory data in the form of memory words. The memory 120 may be configured to store memory words of a predetermined size, e.g., an 8 bit byte, a 4 bit nibble, or other size. As seen in FIG. 1, Mem_Line 0 130 includes M number of memory words, including the memory words labeled as Mem_Word 0 140, Mem_Word 1 141, Mem_Word 2 142, and Mem_Word M 143. In one implementation, the memory 120 stores 32 byte-sized memory words in each memory line. Thus, each memory line stores 256 bits of memory data as well as additional parity protection data.

The parity enabled memory system 100 implements parity protection for memory data stored in the memory 120, e.g., memory words. The memory system 100 implements parity protection by allocating a parity protection bit for each memory word in the memory. The memory 120 also includes designated locations to store parity protection bits for memory data (e.g., memory words).

The parity locations may be designated by a memory system specification for the memory 120. For example, in the memory system 100, a memory system specification for the memory 120 may designate specific locations in the memory 120 to hold parity information. For example, the specification may identify that parity bits are interleaved between the memory words in parity protection bit locations. As seen in the example in FIG. 1, memory line 0 includes M number of designated locations for parity protection bits, including designated parity locations 150-153 interleaved between memory words 140-143. The parity location 150 stores the parity protection bit p0 for Mem_Word 0 140, the parity location 151 stores the parity protection bit p1 for Mem_Word 1 141, and so on.

The memory system specification may be a data sheet, data book, or other architecture document that explains features of the memory 120 and their intended use (e.g., using bits as parity bits). As another example, the memory system specification may document an existing memory system architecture that is licensed to system manufacturers. The license may prevent the manufacturer from modifying certain parts of the memory architecture, such as the location of the parity bits or the arrangement of words in the memory lines. One particular example of a memory system specification is the cache controller memory architecture licensed by ARM Holdings of Cambridge England. Despite the designation by the memory system specification of certain bits as parity bits, the techniques described below implement ECC support instead. The adaptation of the parity bits as ECC bits avoids the need to pursue an extremely costly implementation of standard ECC support in the memory. Part of the cost arises from the fact that close to one half of the area of a typical application processor is L2 cache, and adding ECC would increase the area by approximately 60%. The memory controller 110 also controls access to the memory 120, including memory accesses to perform a read operation or a write operation. Thus, the memory controller 110 may send various control data to the memory 120, including any of the exemplary data or signals discussed above. The memory system 100 may support memory accesses, e.g., write or read operations, of a predetermined atomic size. In FIG. 1, the memory system 100 supports individual memory word updates. That is, the memory controller 110 may send control data to the memory 120 that specifies the update of any individual memory word on a particular memory line. As one example in a memory 120 that stores byte sized memory words, the memory system 100 supports write operations updating individual bytes in the memory 120.

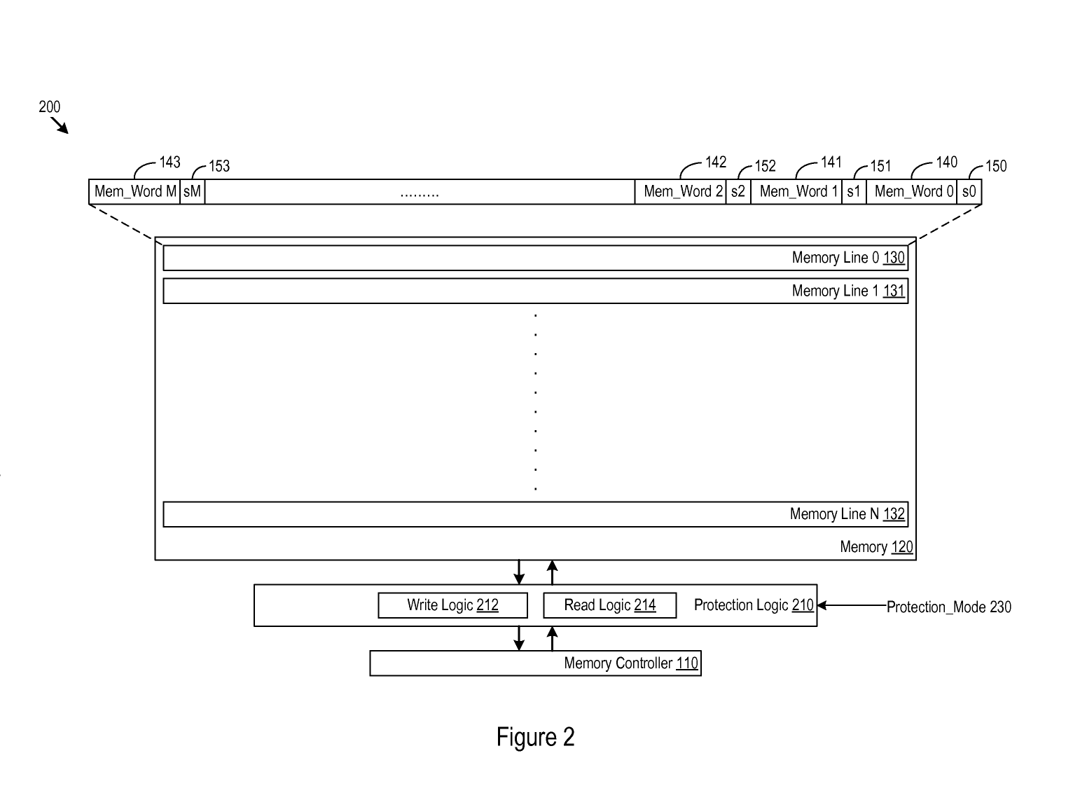

FIG. 2 shows an example of a system 200 that provides ECC protection in a parity enabled memory. The system 200 may include a memory controller 110 and a memory 120 configured as discussed in FIG. 1. The system 200 may also include protection logic 210 in communication with the memory controller 110 and the memory 120. The protection logic 210 may receive control data from the memory controller 110 and interface with the memory 120 to perform a write operation, a read operation, or both. As explained in greater detail below, the protection logic 210 may implement ECC protection for memory data stored in the memory 120 instead of parity protection.

For example, when performing a write operation, the protection logic 210 may obtain data to write into the memory 120 as memory data. If ECC mode is set for the write, then the protection logic 210 may then compute ECC protection data for the memory data (e.g., an ECC syndrome) and store the computed ECC protection data at locations in the memory 120 designated as parity locations. For example, in FIG. 2, the protection logic 210 has stored ECC protection bits labeled as s0, s1, s2, and sM at parity locations 150, 151, 152, and 153 respectively. In one implementation, the protection logic 210 includes write logic 212 to provide ECC protection as part of performing a write operation to the memory 120. If ECC mode is not set, then the memory controller 110 may instead compute and store parity according to the memory system specification. Or, in one implementation, the protection logic 210 may compute parity to store in the memory 120 when the memory controller 110 does not provide parity data.

As another example, when performing a read operation, the protection logic 210 may read memory data from the memory 120. The protection logic 210 may also read protection data for the memory data from locations in the memory 120 designated as parity locations for the memory data. The protection logic 210 may interpret the protection bits as ECC protection bits instead of parity bits. When correctable error is determined in the data, the protection logic 210 may correct the correctable error in the data using the ECC protection bits. In one implementation, the protection logic 210 includes read logic 214 to providing ECC protection as part of performing a read operation from the memory 120.

The protection logic 210 may provide ECC protection in any number of forms. As examples, the protection logic 210 may implement ECC protection using any hamming code, Shor code, triple modular redundancy, or other protection schemes. For a particular ECC word size, the protection logic 210 may implement ECC protection that includes, for example, Single Error Correction (SEC) capability, Double Error Detection (DED) capability, both SEC and DEC (SECDED), double error correction, triple error detection or correction, and beyond, or combinations thereof.

In one implementation, the protection logic 210 may provide ECC protection to memory data that is transparent to the memory controller 110. In other words, the protection logic 210 may provide ECC protection memory data stored without any modification to the memory controller 110 or to the memory 120. Thus, no potentially expensive architecture license may be needed to implement the ECC support. Because the memory controller 110 does not change, the memory controller 110 continues to send parity protection data or receive parity protection data. The protection logic 210 may also maintain any predetermined atomic access size for memory accesses supported by the memory controller 110, e.g., maintaining updates to individual memory words in the memory 120. Further, in one implementation, the protection logic 210 may implement ECC protection in the memory 120 without additional memory overhead or memory configuration changes.

The memory system 200 may operate in different memory protection modes. For example, the memory system 200 may receive memory protection configuration indicator that may indicate whether the protection logic 210 should implement ECC protection for memory accesses to the memory 120 or whether the memory system 200 should implement parity protection, e.g., as described in FIG. 1. In FIG. 2, the protection logic 210 may obtain a memory protection configuration indicator, e.g., through the protection mode signal 230. The protection logic 210 may receive the protection mode signal 230 from, as examples, external logic or the memory controller 110.

The protection logic 210 may process data received from the memory controller 110 or read from the memory 120 differently depending on the memory protection configuration indicator. For example, the protection logic 210 may selectively interpret protection bits for memory data as either parity bits or ECC bits depending on the memory protection configuration indicator. The protection logic 210 may also obtain protection bits for data to be written into the memory 120 depending on the memory protection configuration indicator. For example, the protection logic 210 may obtain protection bits for the data as computed ECC protection bits for the data or as parity data received from the memory controller 110 depending on the memory protection configuration indicator.

When the memory protection configuration indicator specifies implementing parity protection, the memory system 200 may operate similarly to the parity enabled memory system 100 described in FIG. 1. In one implementation, the memory system 200 may disable the protection logic 210 when the memory protection configuration indicator specifies implementing parity protection, allowing data to pass between the memory controller 110 and the memory 120 without processing by the protection logic 210. When the memory protection configuration indicator specifies implementing ECC protection, the protection logic 210 may provide ECC protection as part of performing memory access operations to the memory 120.

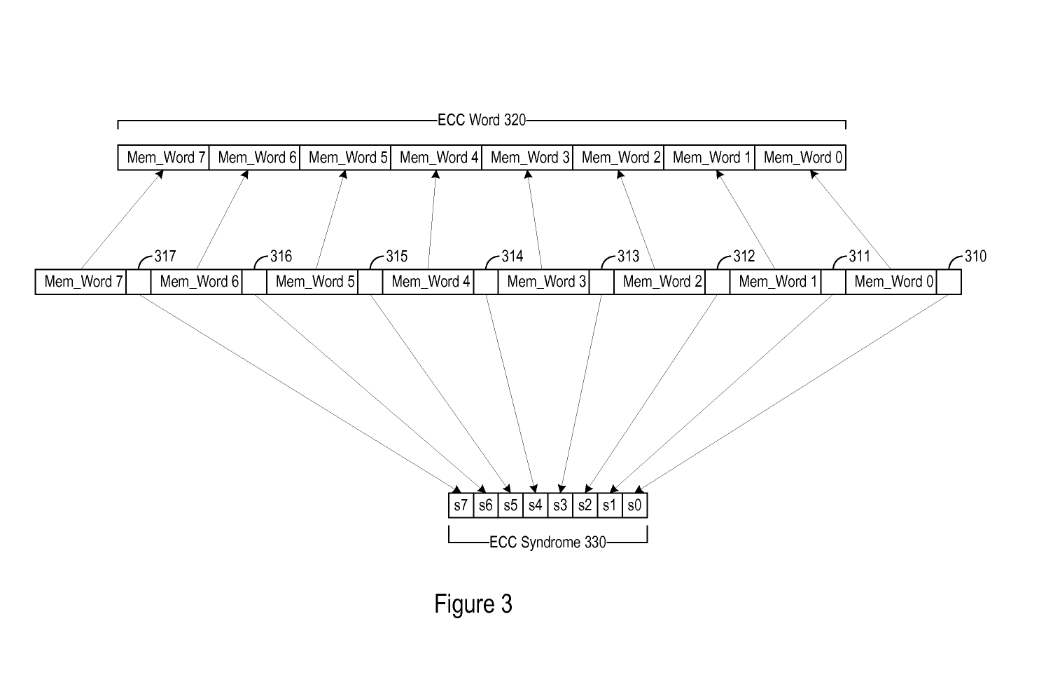

The ECC protection provided by the protection logic 210 may provide ECC protection to the memory 120 on an ECC word granularity. An ECC word may contain any number of memory words and may be associated with any number of ECC protection bits. FIG. 3 shows an example 300 of an ECC word and ECC protection bits. The example 300 shown in FIG. 3 includes 8 memory words labeled as Mem_Word 0-7 that may be stored in the memory 120. For example, the memory words 0-7 may be stored as part of a memory line in the memory 120. Designated parity locations 310-317 may be interleaved between each of the memory words 0-7.

The protection logic 210 may group any number of memory words together to form an ECC word. In the example 300 shown in FIG. 3, the protection logic 210 groups 8 memory words (e.g., Mem_Word 0-7) as the ECC word 320. Thus, the ECC word 320 includes the data stored in the memory words 0-7. The protection logic 210 may also use any number of the parity locations of the grouped memory words to store ECC protection bits for the ECC word 320. As seen in FIG. 3, the protection logic 210 stores 8 ECC protection bits identified as s0-s7 in the designated parity locations 310-317 of the memory words 0-7. The 8 ECC protection bits may form an ECC syndrome 330 for the ECC word 320. The ECC syndrome 330 may support ECC protection for the ECC word 320, such as SECDED protection.

The protection logic 210 may form an ECC word by grouping any number of memory words in the memory 120. In one implementation, the protection logic 210 may form an ECC word such that the number of parity bits allocated to the grouped memory words is equal to or more than the minimum number of ECC protection bits used to provide ECC protection for the ECC word. To illustrate, each of the memory words 0-7 in FIG. 3 may be a byte (i.e., 8 bits) in length. The protection logic 210 may group the 8 memory words 0-7 together to form an ECC word 64-bits in length. Providing SECDED protection to a 64-bit word may be accomplished using 8 ECC protection bits. Thus, the 8 existing parity bits associated with the 8 grouped memory words 0-7 is equal to the 8 bits of ECC protection data required to provide SECDED protection for the 64-bit ECC word. As such, no additional memory overhead is needed to implement SECDED protection for an 8-byte ECC word since the 8 existing parity bits are sufficient to store the 8 ECC protection bits of the ECC word.

In another example, the protection logic 210 may form an ECC word by grouping a number of memory words such that the number of parity bits associated with the grouped memory words is greater than the minimum number of ECC protection bits used to implement ECC protection for the ECC word. In this example, the protection logic 210 may store ECC protection bits in some of the designated parity locations of the grouped memory words while some of the designated parity locations are unused. To illustrate, the protection logic 210 may group 16 byte-sized memory words to form an ECC word that is 128 bits in length. Implement SECDED protection for a 128 bit ECC word may require 9 bits of ECC protection data. As such, the protection logic 210 may store ECC protection bits in 9 of the 16 designated parity bit locations for the 16 grouped memory words. The remaining 7 designated parity bit locations may be unused as part of the SECDED protection provided by the protection logic 210.

Thus, by forming ECC words that include multiple memory words and using the associated parity locations of the multiple memory words to store ECC protection data, the protection logic 210 may implement ECC protection in a parity enabled memory, e.g., the memory 120. In doing so, the protection logic 210 may provide ECC protection using the existing parity enabled configuration of the memory 120, thus simplifying the ECC implementation design.

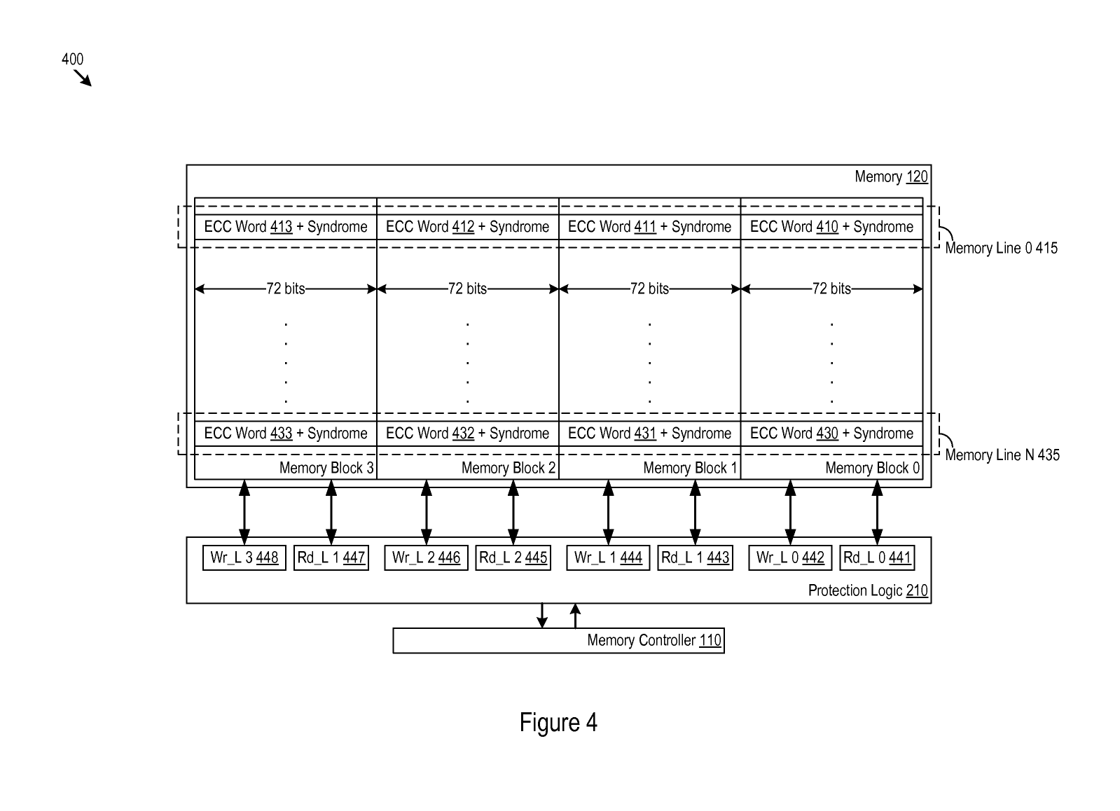

FIG. 4 shows an example of a system 400 that provides ECC protection in a parity enabled memory. The memory 120 may be divided in any number of ways. For example, the memory 120 may be divided into multiple memory banks to decrease access time latency. Each memory bank may store entire memory lines. The memory 120, or a memory bank, may also be divided into any number of memory blocks. Each memory block may act as a separate logic memory unit and include associated access logic. A memory block may store a portion of a memory line, and multiple memory blocks may be accessed to perform a read of a memory line. In the exemplary system 400 shown in FIG. 4, the memory 120 is divided into four equally sized memory blocks labeled as memory blocks 0-3. In one example, each memory line, e.g., memory line 0 415, may store 32 bytes of memory data and 32 corresponding parity protection bits. In this example, each of the memory blocks 0-3 stores a portion, e.g., 8 bytes, of a memory line in the memory 120. Each memory block 0-3 may also store parity protection data associated with the 8 bytes of memory data stored for each memory line. Designated parity protection locations may be interleaved between the 8 memory words of each memory line stored a memory block. Thus, in this example, each of the memory blocks 0-3 may store 72 bits of a memory line, which includes 8 bytes of memory data and 8 bits of protection data stored in designated parity bit locations.

The protection logic 210 may form an ECC word using the 8 bytes of memory data of a memory line stored in each of the memory blocks 0-3. The protection logic 210 may also use the 8 bits of designated parity locations to store ECC protection bits for the ECC word instead of parity bits. As seen in FIG. 4, memory line 0 415 includes 8 bytes of memory data stored as ECC word 410 in memory block 0, 8 bytes of memory data stored as ECC word 411 in memory block 1, and so on. Memory block 0 also stores 8 bits of ECC protection data, e.g., an ECC syndrome, associated with ECC word 410. Similarly, memory block 1 stores ECC protection data, an 8 bit ECC syndrome, associated with ECC word 411, and so on.

In one implementation, each memory block of the memory 120 includes dedicated logic for implementing ECC protection for memory accesses to the memory block. As seen in FIG. 4, read logic 0 441 and write logic 0 442 may respectively provide ECC protection for read memory accesses and write memory accesses to memory block 0. Read logic 443, 445, and 447 as write logic 444, 446, and 448 may similarly provide ECC protection for memory accesses to memory blocks 1, 2, and 3 respectively.

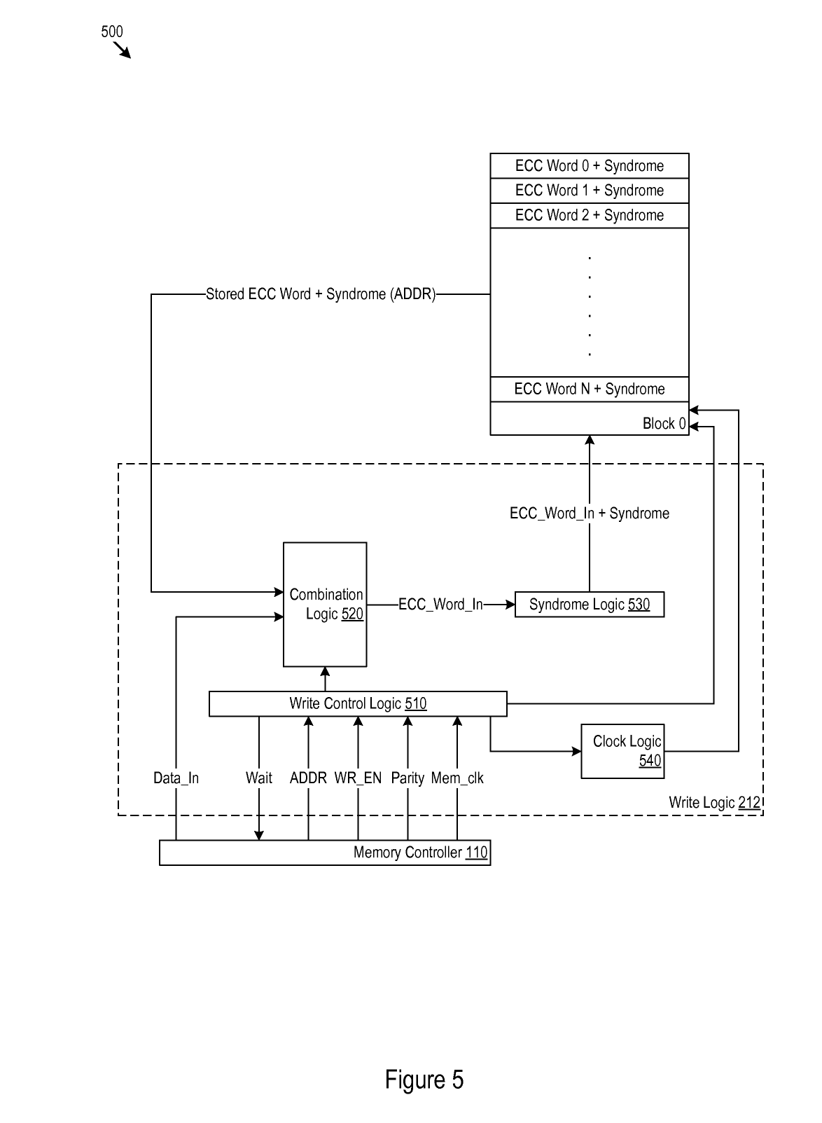

FIG. 5 shows an example of a system 500 for writing an ECC word into a parity enabled memory. The system 500 includes write logic 212 that may perform a write operation to any type of memory, such as the memory 120. The write logic 212 may also implement ECC protection as part of performing the write operation, e.g., when writing data to memory block 0 of FIG. 5. In one implementation, the write logic 212 may include write control logic 510, combination logic 520, syndrome logic 530, and clock logic 540, as seen in FIG. 5. The write logic 212 may receive control data from the memory controller 110, including as examples a memory clock signal, parity data, a write enable line, a memory address, and write data.

As discussed above, the memory controller 110 may support memory updates of a predetermined atomic size, e.g., individual memory words. The write logic 212 may satisfy the memory-word writeability requirement of a memory controller 110 even though an ECC word may comprise multiple memory words. To do so, the write control logic 510 may determine the scope of which a write operation will update an ECC word. For instance, the write control logic 510 may identify when a write operation will fully update an ECC word, partially update the ECC word, or not update the ECC word. The write control logic 510 may determine the scope of a write operation by analyzing control data received from the memory controller 110, e.g., by parsing a write enable signal received from the memory controller 110. The write enable signal may identify specific memory words that a write operation will update, for example as a bit string identifying memory word positions of a memory line that will be updated by the write operation.

The write control logic 510 may determine if a write operation will perform a full update to an ECC word, a partial update, or no update. When the write operation does not affect an ECC word, e.g., the write enable signal indicates no memory words contained in the ECC word will be updated by the write operation, the write control logic 510 may forego further action. For example in FIG. 5, if the WR_EN signal received by the write control logic 510 indicates that no data from an ECC word associated with the memory address ADDR will be updated, then the write control logic 510 may forego further action as the write operation may not affect any data in memory block 0.

When the write control logic 510 identifies a full write to an ECC word, e.g., when the WR_EN signal indicates all of the memory words of an ECC word will be updated by a write operation, the write control logic 510 may initiate a write operation. The combination logic 520 may identify a portion of the write data to be written into a memory. For example, when a memory 120 is divided into multiple memory blocks, the memory controller 110 may pass an entire memory line as write data to protection logic associated with each memory block. In FIG. 5, the control data labeled as Data_In may be a memory line that includes memory words to be written into multiple memory blocks of a memory 120. In this example, only a portion of the write data, e.g., Data_In, corresponds to data stored in a particular memory block. Thus, the combination logic 520 may determine a relevant portion of the write data to be stored in the memory block.

After identifying a full update to an ECC word, the write control logic 510 may instruct the combination logic 520 to pass the determined relevant portion of the write data received from the memory controller 110. In FIG. 5, the combination logic 520 may send the relevant portion of Data_In to the syndrome logic 530 as ECC_Word_In. When the write operation fully updates an ECC word in memory block 0, ECC_Word_In may include the memory data from Data_In. The syndrome logic 530 may compute ECC protection bits for the ECC_Word_In, e.g., by computing an ECC syndrome according to a SECDED hamming algorithm. The syndrome logic 530 may then send the ECC_Word_In and the computed ECC protection bits, e.g., an ECC syndrome, to be written into memory block 0. The write control logic 510 may send control signals to the memory block controlling the write operation, e.g., a memory clock pulse and a write signal. Thus, the write logic 212 may store the ECC_Word_In and the computed ECC protection bits in memory block 0. The write logic 212 may store the ECC protection bits in locations in the memory block designated as parity locations for the memory words comprising ECC_Word_In.

When the write control logic 510 identifies a partial write to an ECC word, e.g., when the WR_EN signal indicates some, but not all, of the memory words of an ECC word will be updated by a write operation, the write control logic 510 may initiate a read-merge-write transaction. As the write operation will partially update an ECC word in memory block 0, data provided by the memory controller 110, e.g., Data_In, may include only a portion of the data of an ECC word. However, the write logic 212 may use the entire ECC word to compute the ECC protection bits for the ECC word.

To properly compute ECC protection bits for a partially updated ECC word, the write logic 212 may obtain the remaining portion of the ECC word that may not be affected by the partial write operation. When the write control logic 510 identifies a partial write, the write control logic 510 may first perform a read operation from the memory to obtain the stored ECC word to be updated, e.g., the ECC word associated with memory address provided by the memory controller 110. The combination logic 520 may receive the stored ECC word, as read from the memory. The combination logic 520 may also identify the relevant portions of the Data_In received from the memory controller 110 that correspond to the partial update of the

ECC word. Then, the combination logic 520 may merge the stored ECC word and the relevant portions of update data from Data_In, obtaining a partially updated ECC word. Thus, the partially updated ECC word may contain a first portion of data from Data_In, e.g., memory words updated by the write operation. The partially updated ECC word may also contain a remaining portion that contains data from the stored ECC word that were not updated by the write operation.

The combination logic 520 may then send the partially updated ECC word to the syndrome logic 530 as the ECC_Word_In. Then, the syndrome logic 530 may compute ECC protection bits for the partially updated ECC word using both the updated data portion received from the memory controller 110 and the remaining non-updated data portion obtained as part of the stored ECC word. Next, the write logic 212 may store the ECC_Word_In, e.g., the partially updated ECC word, and the computed ECC protection bits in memory block 0, thus overwriting the stored ECC word previously retrieved and previous protection bits for the overwritten stored ECC word.

The write logic 212 may adjust timing of the system 500 when a partial write to an ECC word is identified. As described above, the write logic 212 may handle a partial write scenario by performing a read-merge-write transaction. The read-merge-write transaction may require two accesses to the memory, a first memory access to read the stored ECC word for merging with the updated memory data and a second memory access to write the partially updated ECC word into the memory. In one implementation, the write control logic 510 may delay further memory accesses to a memory until the read-merge-write transaction completes. For example, the write control logic 510 may send a wait signal to the memory controller 110 that may pause the operation of the memory controller 110 and provide additional latency for the write logic 212 to handle the partial write to the ECC word, e.g., by performing the read-merge-write transaction.

To handle the partial write to an ECC word, the clock logic 540 may adjust a memory clock signal to support multiple accesses to the memory. In one implementation, the memory controller 110 may specify memory access timing during a write operation by providing a memory clock signal providing a single access to the memory, e.g., a single pulse to perform the write operation. However, as the write logic 212 may require multiple accesses to the memory to handle the partial write, the write control logic 510 may send a partial update indication to the clock logic 540 when a partial write is detected. In response, the clock logic 540 may generate multiple clock pulses and allow multiple accesses to the memory in order to support the read-merge-write transaction.

Thus, as described above, the write logic 212 may provide ECC protection for memory data written to a memory by computing and storing ECC protection bits in the memory, e.g., at designated parity locations. In one implementation, the write logic 212 may provide ECC protection that is transparent to a memory controller 110 that sends parity data. In this implementation, the memory controller 110 may send parity data, which the write logic 212 may ignore or discard.

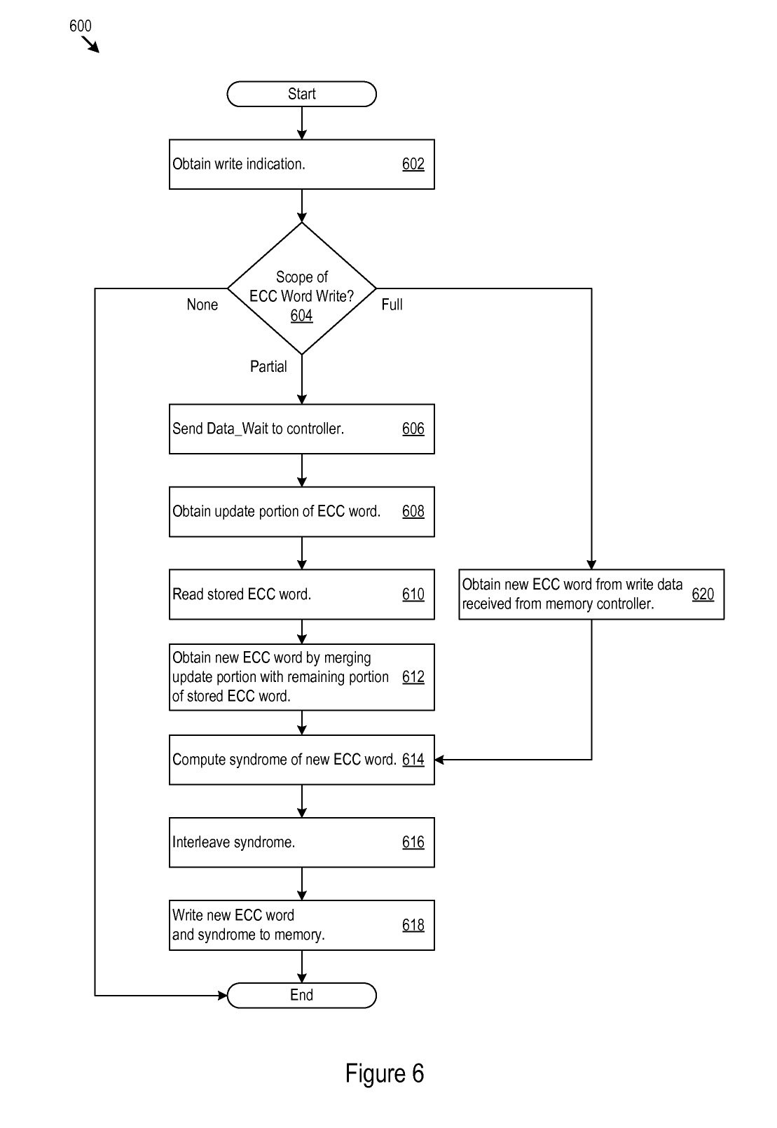

FIG. 6 shows an example of logic 600 that may be implemented as hardware, software, or both. For example, the logic 600 may be implemented as part of the protection logic 210, e.g., as the write logic 212. The write logic 212 may provide ECC protection as part of a write operation to a memory associated with the write logic 212. For example, the write logic 212 may be associated with a particular memory block, e.g., memory blocks 0-3 in FIG. 4 or memory block 0 in FIG. 5. In operation, the write logic 212 may obtain a write indication (602), for example by receiving control data from the memory controller 110 specifying a write operation. The write logic 212 may receive for example, a write enable signal, write data, a memory address, a memory clock, or other data or control signals.

The write logic 212 may next determine the scope the write operation will affect one or more ECC words in a memory (604). For example, the memory controller 110 may provide a write enable signal identifying affected memory words of a memory line. When a memory line is stored across multiple memory blocks, e.g., as seen in FIG. 4, the write logic 212 of a memory block may identify and analyze an applicable portion of the write enable signal. When the write logic 212 determines that a write operation will not affect an ECC word in the memory block, the write logic 212 may forego further action.

When the write logic 212 identifies the write operation will partially update an ECC word in the memory block, the write logic 212 may send a wait signal to the memory controller 110 (606) that may pause operation of the memory controller 110 or provide additional latency to the write logic 212 to handle the partial update scenario. The write logic 212 may handle the partial write to an ECC word by performing a read-merge-write transaction. The write logic 212 may obtain an update portion of the new ECC word to be stored in the memory as a result of the write operation (608). The update portion of the new ECC word may include updated data for memory words affected by the write operation. As one example, the write logic 212 may obtain the update portion of the new ECC word from write data received from the memory controller 110. The write logic 212 may also obtain the remaining portion of the new ECC word that will not be affected by the write operation, e.g., by reading a stored ECC word from the memory block (610) and determining the data of the non-updated portion of the new ECC word.

Next, the write logic 212 may obtain a new ECC word (e.g., the partially updated ECC word) (612) that includes the update portion obtained from the memory controller 110 and the remaining portion obtained from the stored ECC word. The write logic 212 may then generate ECC protection bits for the new ECC word, such as by computing a syndrome of the new ECC word (614). In one implementation, the write logic 212 may interleave the computed ECC protection bits among memory words contained in the new ECC word (616). The write logic 212 may subsequently write the new ECC word and the computed ECC protection bits into the memory block (618). The write logic 212 may store the computed ECC protection bits in any number of designated parity locations of memory words contained in the ECC word.

Referring again to determining the degree the write operation will affect one or more ECC words in a memory, the write logic 212 may determine that the write operation will perform a full update to an ECC word in the memory block. Upon identifying a full update scenario, the write logic 212 may obtain the new ECC word entirely from write data received from the memory controller 110 (620). Then, the write logic 212 may compute ECC protection bits for the new ECC word (614), interleave the ECC protection bits among memory words contained in the new ECC word (616), and store the new ECC word and computed ECC protection bits into the memory block (618).

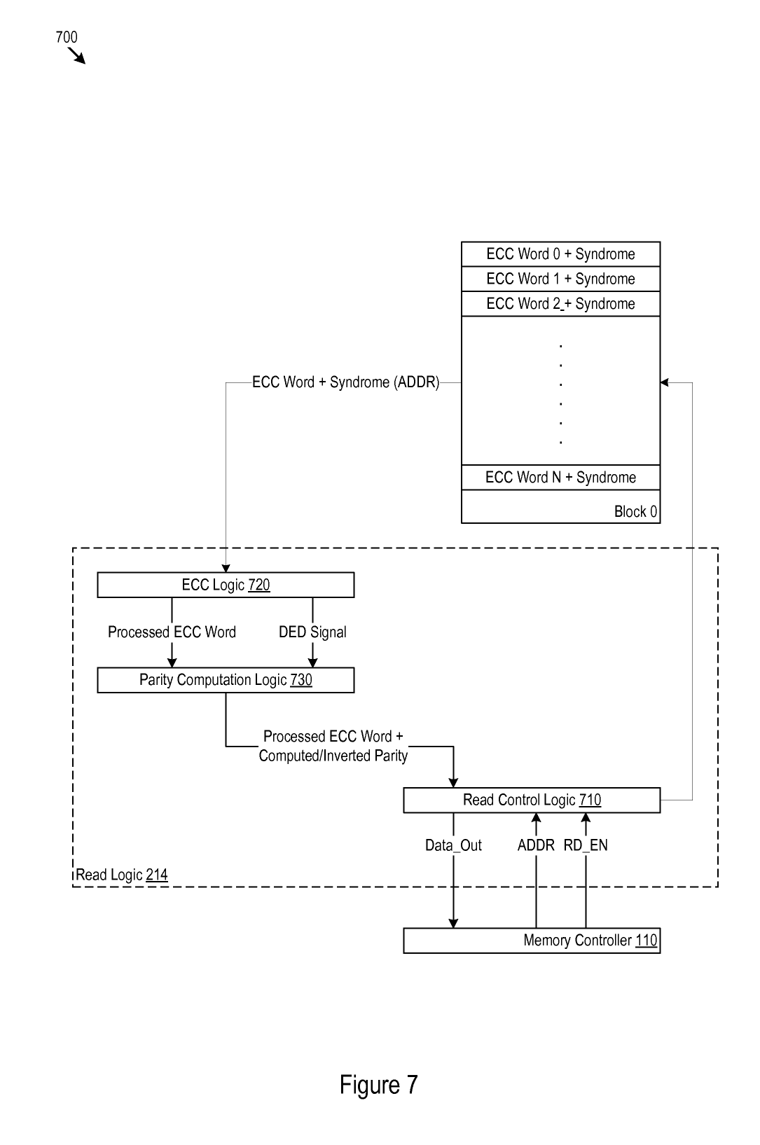

FIG. 7 shows an example of a system 700 for reading an ECC word from a parity enabled memory. The system 700 may include read logic 214 that may perform a read operation on any type of memory, e.g., the memory block 0 seen in FIG. 7. The read logic 214 may also implement ECC protection as part of performing the read operation, e.g., when reading data from memory block 0. In one implementation, the read logic 214 may include read control logic 710, ECC logic 720, and parity computation logic 730, as depicted in FIG. 7.

The read control logic 710 may obtain a read indication, for example by receiving control signals from the memory controller 110 requesting data from a memory associated with the read logic 214. For example, the read control logic 710 may receive a read enable signal and a memory address from the memory controller 110. The read control logic 710 may then perform a read of the memory block to obtain data associated with the provided memory address, e.g., memory data forming an ECC word. During the read operation, the read logic 214 may also read protection bits associated with the ECC word, e.g., from locations designated as parity locations in the memory block. The read logic 214 may interpret the protection bits as ECC protection bits instead of as parity bits, for example as an ECC syndrome of the ECC word.

The ECC logic 720 may receive the ECC word and protection bits read from the memory block. The ECC logic 720 may process the ECC word to obtain a processed ECC word. The ECC logic 720 may process the ECC word using the ECC protection bits according to any ECC technique. For example, the ECC logic 720 may identify the protection bits of the ECC word as an ECC syndrome. Or, the ECC logic 720 may analyze the ECC protection bits and the ECC word to provide SECDED protection.

As part of providing ECC protection to an ECC word read from the memory block, the ECC logic 720 may determine whether there is correctable error in the ECC word. For example, the ECC logic 720 may use the ECC syndrome to determine whether a single-bit error has occurred in the data. If so, the ECC logic 720 may correct the correctable error using the ECC protection bits, e.g., syndrome. When the ECC logic has identified correctable error, the ECC logic 720 may obtain a processed ECC word by correcting the correctable error in the ECC word.

The ECC logic 720 may also determine whether there is uncorrectable error in the ECC word. For example, the ECC logic 720 may use the ECC protection bits to determine that a double-bit (or more) error has occurred in the ECC word. The ECC logic 720 may identify a multiple-bit error as uncorrectable error and, in response, send an uncorrectable error signal to the parity computation logic 730, e.g., via the DED signal. When the ECC logic 720 has identified uncorrectable error, the ECC logic 720 may obtain a processed ECC word that remains the same as the ECC word just read from memory, e.g., an ECC word containing uncorrectable error. Similarly, when the ECC logic 720 determines that no error has occurred in the ECC word, the ECC logic 720 may obtain a processed ECC word that remains the same as the ECC word, e.g., an ECC word with no error. The ECC logic 720 may send the processed ECC word to the parity computation logic 730.

In one implementation, the read logic 214 may provide ECC protection that is transparent to the memory controller 110. In this implementation, the memory controller 110 may send parity data or expect parity data as a result of memory access operations. As such, the read logic 214 may provide parity data to the memory controller 110 instead of ECC protection data. The read logic may provide parity data to the memory controller 110 that may indicate whether a processed ECC word contains error.

The parity computation logic 730 may compute parity of a processed ECC word does not contain any error. The parity computation 730 may obtain an indication that the processed ECC word is free of error from the ECC logic 720, e.g., via the DED signal. When the DED signal indicates the processed ECC word does not contain uncorrectable error, the parity computation logic 730 may compute parity for the processed ECC word that indicates no parity error. For example, the parity computation logic 730 may compute parity for each of the memory words contained in the processed ECC word. The parity computation logic 730 may then send the processed ECC word and the computed parity to the read control logic 710. The read control logic 710 may then send the Processed ECC Word and the computed parity to the memory controller 110 as a result of the read operation, e.g., as Data_Out.

When the DED signal indicates that a processed ECC word contains uncorrectable error, the parity computation logic 730 may provide an indication to the memory controller that the processed ECC word contains data error. For example, the parity computation logic 730 may compute parity bits for the processed ECC word that indicates parity error. In one implementation, the parity computation logic 730 may first compute parity for the ECC word, e.g., by computing the parity of each of memory word contained in the processed ECC word. The parity computation logic 730 may then invert at least one of the computed parity bits, thus indicating parity error. The parity computation logic 730 may then send the processed ECC word and the inverted parity to the read control logic 710. The read control logic 710 may then send the processed ECC word (containing error) and the inverted parity to the memory controller 110 as a result of the read operation, e.g., as Data_Out. In this way, the read logic 214 may provide an uncorrectable error indication to the memory controller 110. By purposefully inverting a parity bit, the read logic 217 may signal to the memory controller that the processed ECC word contains error.

Thus, as discussed above, the read logic 214 may provide SECDED protection to ECC words read from the memory block, e.g., by identifying and correcting single bit errors in an ECC word and by sending an uncorrectable error indication to the memory controller 110 when a multiple-bit error is detected.

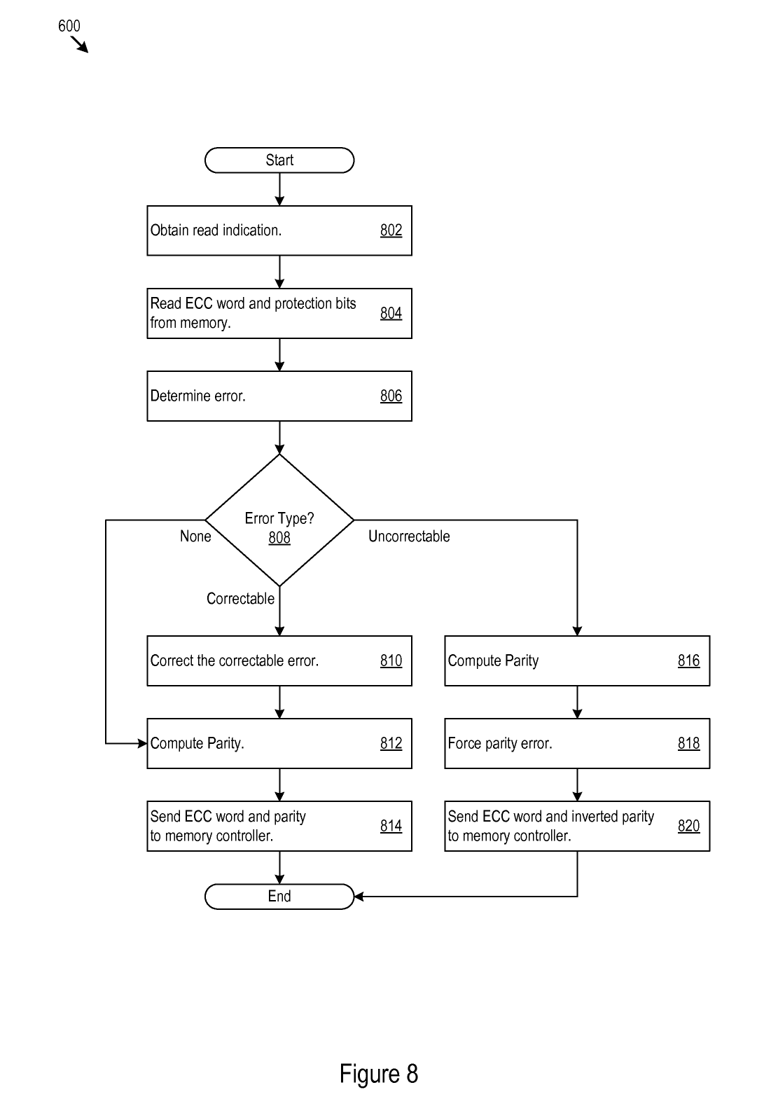

FIG. 8 shows an example of logic 800 that may be implemented as hardware, software, or both. For example, the logic 800 may be implemented as part of the protection logic 210, e.g., as the read logic 214. The read logic 214 may control read operations and provide ECC protection for any number or types of memories. The read logic 214, as discussed below, may be associated with a particular memory block, e.g., any of the memory blocks 0-3 in FIG. 4.

In operation, the read logic 214 may obtain a read indication (802), for example from control data sent from a memory controller 110. The read logic 214 may then perform a read operation to obtain an ECC word associated with a memory address provided the memory controller 110 (804). The read logic 214 may also read protection bits associated with the read ECC word, e.g., protection bits stored at designated parity locations for memory words contained in the ECC word. The read logic 214 may interpret the protection bits as ECC protection bits, e.g., as protection bits that together form a syndrome for the ECC word.

Next, the read logic 214 may then determine whether the read ECC word includes error using the ECC syndrome (806). The read logic 214 may also determine an error type, such as no error, correctable error, or uncorrectable error (808). In one implementation, the read logic 214 may provide SECDED protection, and the read logic 214 may identify a single bit error in the ECC word as correctable error and a multiple-bit error, e.g., double-bit error, in the ECC word as uncorrectable error.

When the read logic 214 determines there is correctable error in the read ECC word, the read logic 214 may correct the correctable error (810), e.g., by employing a SEC technique using the ECC protection bits. The read logic 214 may then compute parity for memory words that comprise the ECC word (812) and subsequently send the read ECC word and the computed parity to the memory controller 110 (814). In one implementation, the read logic 214 may send the ECC word and computed parity to additional logic associated with multiple memory blocks instead of the memory controller 110. The additional logic may merge multiple ECC words and computed parity received from read logics associated different memory blocks, e.g., memory blocks that together store a memory line of a memory 120. The additional logic may obtain a merged memory line and send the merged memory line to the memory controller 110 in response to a read operation.

Referring again to determining error type (808), the read logic 214 may compute parity of memory words contained in the ECC word (812) upon determining there is no error in the ECC word. Then, the read logic 214 may send the ECC word and computed parity to the memory controller 110 (814). When the read logic 214 determines that there is uncorrectable error in the ECC word read from the memory block, the read logic 214 may compute parity (816) for memory words comprising the ECC word. The read logic 210 may then force a parity error (818) for the read ECC word, for example by inverting any number of the computed parity bits. In other embodiments, the read logic 214 may force a parity error by asserting an error signal or setting a parity error register value. Upon forcing the parity error, the read logic 214 may send the ECC word and inverted parity to the memory controller (820). In this way, the read logic 214 may provide an error indication to the memory controller 110 that the read ECC word includes error, e.g., uncorrectable error.

The methods, devices, and logic described above may be implemented in many different ways in many different combinations of hardware, software or both hardware and software. For example, all or parts of the system may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. All or part of the logic described above may be implemented as instructions for execution by a processor, controller, or other processing device and may be stored in a tangible or non-transitory machine-readable or computer-readable medium such as flash memory, random access memory (RAM) or read only memory (ROM), erasable programmable read only memory (EPROM) or other machine-readable medium such as a compact disc read only memory (CDROM), or magnetic or optical disk. Thus, a product, such as a computer program product, may include a storage medium and computer readable instructions stored on the medium, which when executed in an endpoint, computer system, or other device, cause the device to perform operations according to any of the description above.

The processing capability of the system may be distributed among multiple system components, such as among multiple processors and memories, optionally including multiple distributed processing systems. Parameters, databases, and other data structures may be separately stored and managed, may be incorporated into a single memory or database, may be logically and physically organized in many different ways, and may implemented in many ways, including data structures such as linked lists, hash tables, or implicit storage mechanisms. Programs may be parts (e.g., subroutines) of a single program, separate programs, distributed across several memories and processors, or implemented in many different ways, such as in a library, such as a shared library (e.g., a dynamic link library (DLL)). The DLL, for example, may store code that performs any of the system processing described above. While various embodiments of the invention have been described, it will be apparent to those of ordinary skill in the art that many more embodiments and implementations are possible within the scope of the invention. Accordingly, the invention is not to be restricted except in light of the attached claims and their equivalents.

What is claimed is:

1. A method comprising:
reading data from a memory;
reading protection bits for the data from the memory from locations designated as parity locations for the data; and
interpreting the protection bits as Error Correcting Code (ECC) protection bits instead of as parity bits.

2. The method of claim 1, further comprising:
determining whether there is a correctable error in the data; and
when there is a correctable error in the data, correcting the correctable error using the ECC protection bits to obtain corrected data.

3. The method of claim 2, further comprising:
computing parity for the corrected data to indicate no parity error; and
sending the corrected data and the parity to a memory controller that expects parity data.

4. The method of claim 2, where determining whether there is correctable error in the data comprises determining whether there is a single bit error in the data.

5. The method of claim 1, further comprising:
determining whether there is an uncorrectable error in the data; and
when there is an uncorrectable error in the data, determining parity bits for the data that indicate a parity error; and
providing the parity bits to a memory controller that expects parity bits.

6. The method of claim 1, where determining parity bits for the data that indicate a parity error comprises inverting a parity bit that indicates no parity error.

7. The method of claim 5, where determining whether there is uncorrectable error in the data comprises determining whether there is a multiple bit error in the data.

8. A method comprising:
obtaining data to write into a memory;
computing ECC protection bits for the data; and
storing the ECC protection bits in locations in the memory designated as parity locations for the data.

9. The method of claim 8, where the locations are designated as parity locations by a memory system specification for the memory.

10. The method of claim 8, where the data comprises a first portion of an ECC word; and where computing comprises:
obtaining a remaining portion of the ECC word from the memory;
merging the first portion and the remaining portion to obtain a merged ECC word;
computing the ECC protection bits from the merged ECC word.

11. The method of claim 10, where obtain the remaining portion comprises reading the ECC word from the memory; and further comprising:
writing the merged ECC word and ECC protection bits into the memory.

12. The method of claim 11, further comprising:
adjusting a memory clock signal to support multiple memory accesses, where the multiple memory accesses comprise reading the ECC word from the memory and writing the merged ECC word and ECC protection bits into the memory.

13. The method of claim 10, where computing the ECC protection bits from the merged ECC word comprises computing an ECC syndrome from the merged ECC word providing Single Error Correction Double Error Detection (SECDED) protection.

14. The method of claim 8, where the data comprises a full ECC word; and where computing comprises:
computing the ECC protection bits from the full ECC word.

15. A system comprising:
a memory; and
protection logic in communication with the memory, the protection logic configured to:
obtain a memory protection configuration indicator; and
selectively interpret protection bits for the memory as either parity protection bits or ECC protection bits depending on the memory protection configuration indicator.

16. The system of claim 15, where the protection logic is further configured to:
receive data to store in the memory; and
obtain protection bits for the data depending on the memory protection configuration indicator.

17. The system of claim 16, where the protection logic is configured to obtain protection bits for the data by computing ECC protection bits for the data when the memory protection configuration indicator specifies ECC protection.

18. The system of claim 16, where the protection logic is configured to obtain protection bits for the data by receiving parity information for the data from a memory controller when the memory protection configuration indicator specifies parity protection.

19. The system of claim 15, where the protection logic is further configured to:
read data and protection bits associated with the data from the memory; and
when the protection bits are selectively interpreted as ECC protection bits:
determine whether the data contains correctable error, uncorrectable error, or no error by using the ECC protection bits.

20. The system of claim 19, where the protection logic is further configured to:
correct the correctable error in the data when the data contains correctable error.
